(19) United States
(12) Patent Application Publication
(10) Pub. No.: US 2002/0063279 A1
(43) Pub. Date: May 30, 2002

(54) Tunnel oxide

(76) Inventors: Men-Chee Chen, Dallas, TX (US); Katherine E. Violette, Dallas, TX (US); Cetin Kaya, Plano, TX (US); Rick L. Wise, Plano, TX (US)

Correspondence Address: Jacqueline J. Garner, Texas Instruments Incorporated, PO Box 655474, M/S 3999, Dallas, TX, 75265, US

(21) Appl. No.: 09/726,816

(22) Filed: Nov. 30, 2000

Related U.S. Application Data
(60) Provisional application No. 60/173,177, filed on Dec. 27, 1999.

(51) Int. Cl. H01L 21/336; H01L 29/788

(52) U.S. Cl. 257/317; 438/260

(57) ABSTRACT

A semiconductor device includes a substrate and an oxide layer disposed outwardly from the substrate. The semiconductor device also includes a polysilicon layer disposed outwardly from the oxide layer, the oxide layer having an interface between the oxide layer and the polysilicon layer, the interface having asperities such that the barrier potential between the polysilicon layer and the substrate is reduced in response to the asperities.

### BACKGROUND OF THE INVENTION

Flash memory cells are typically erased via Fowler-Nordheim tunneling mechanisms which require the application of an electrical field across a tunnel oxide. As a integrated circuits become denser to accommodate a greater number of transistors for increased processing power, the gate lengths of microelectronic devices utilized in such integrated circuits decreases significantly. Additionally, the need for portable electronics and wireless applications results in the need for semiconductor devices having decreased power supply requirements. As power supply voltages decrease due to smaller gate lengths and the needs of specific applications, it becomes increasingly difficult to maintain a power supply large enough to generate the electrical field across a tunnel oxide required to erase flash memory cells. This problem arises because the thickness of a tunnel oxide needed in flash memory cells does not decrease in scale with changes in gate length.

One method utilized to lower the strength of the electric field required for flash memory cell erasure involves using a silicon-rich CVD tunnel oxide. However, semiconductor processing steps subsequent to the formation of the silicon-rich tunnel oxide such as, for example, an anneal, may deteriorate the silicon islands that characterize silicon-rich tunnel oxides and that are themselves responsible for allowing tunneling to occur at a lower electrical field than would be required for other tunnel oxides.

Another method of lowering the strength of the electrical field required to achieve erasure of flash memory cells involves the texturing of the tunnel oxide. A textured tunnel oxide has a lower tunneling barrier height, and therefore requires a lower strength electrical field to achieve erasure, because of the enhanced electrical field at the asperities of the interface between an overlying silicon layer and the silicon dioxide tunnel oxide layer. Such texturing has been achieved by either etching the silicon surface prior to the growth of a tunnel oxide or by thermally oxidizing a thin polysilicon layer on the surface of a silicon substrate. However, both of such methods result in a tunnel oxide that is textured at both the top silicon gate interface and the bottom silicon substrate interface. The problem with such texturing is that the surface roughness of the interface between the substrate and the tunnel oxide results in a decrease in carrier mobility in the channel region of a semiconductor transistor, and the performance of such transistor significantly degrades as a result.

### SUMMARY OF THE INVENTION

In accordance with the present invention, an improved tunnel oxide is provided that substantially eliminates or reduces disadvantages and problems associated with previous developed systems and methods.

In one embodiment of the present invention, a semiconductor device is disclosed that includes a substrate and an oxide layer disposed outwardly from the substrate. The semiconductor device also includes a polysilicon layer disposed outwardly from the oxide layer, the oxide layer having an interface between the oxide layer and the polysilicon layer, the interface having asperities such that the barrier potential between the polysilicon layer and the substrate is reduced in response to the asperities.

In a second embodiment, a method of forming a semiconductor device is disclosed that includes forming a thermal oxide layer outwardly from the surface of a substrate and forming a polysilicon layer outwardly from the thermal oxide layer. The method also includes oxidizing the polysilicon layer and forming a gate layer outwardly from the oxidized polysilicon layer, the thermal oxide layer and the oxidized polysilicon layer forming a tunnel oxide layer separating the gate layer from the substrate.

In a third embodiment of the present invention, a method of forming a semiconductor structure is disclosed that includes forming a thermal oxide layer outwardly from the surface of a substrate. The method also includes forming a polysilicon layer outwardly from the thermal oxide layer and oxidizing the polysilicon layer.

Technical advantages of various embodiments of the present invention include providing an improved tunnel oxide layer for use with low voltage applications. A further advantage of various embodiments of the present invention is providing a method of texturing a tunnel oxide that does not result in the degradation of the performance of a transistor. An additional advantage of the present invention is that the strength of an electric field required to erase a flash memory cell is reduced. Yet another advantage of the various embodiments of the present invention is to allow the formation of a textured tunnel oxide layer that can be used to facilitate the integration of flash memory cells in devices having lower power supplies. Other technical advantages will be readily apparent to one skilled in the art from the following figures, descriptions and claims.

### BRIEF DESCRIPTION OF THE DRAWINGS

For a more complete understanding of the present invention and its advantages, reference is now made to the following description taken in conjunction with the accompanying drawings in which:

FIGS. 1A through 1D are a series of schematic cross-sectional diagrams illustrating one embodiment of the formation of a tunnel oxide of a semiconductor device implemented according to the teachings of the present invention.

### DETAILED DESCRIPTION OF THE INVENTION

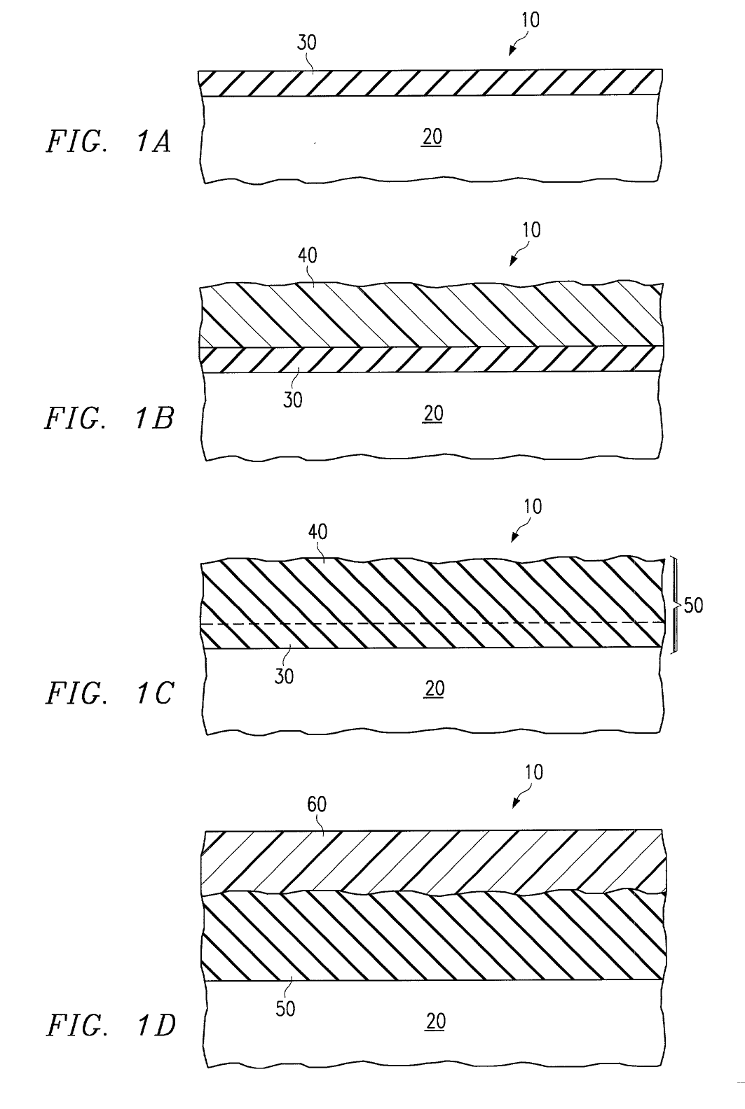

FIGS. 1A through 1D illustrate the formation of a semiconductor device 10 according to one embodiment of the present invention. In particular, FIGS. 1A through 1D describe the use of an improved textured tunnel oxide in order to decrease the barrier potential across a tunnel oxide. Such a decrease means that the strength of an electric field needed to be applied in order to, for example, erase a flash memory cell that includes the textured tunnel oxide may be significantly reduced. In particular, the process described in FIGS. 1A through 1D allows for the growth of a tunnel oxide layer with significant texture or roughness at an interface with, for example, an outerlying layer of polysilicon used to form the floating gate of a transistor, without any deterioration in transistor performance.

FIG. 1A illustrates one embodiment of a schematic cross-sectional diagram of the formation of semiconductor device 10. In particular, FIG. 1A illustrates the formation of a thermal oxide layer 30 on a substrate 20. Substrate 20 is a Noncrystalline silicon substrate; however, substrate 20 may be any other suitable layer of material such as, for example, a metallization layer. Substrate 20 may formed using conventional techniques well known in the field of wafer fabrication and semiconductor processing.

Thermal oxide layer 30 is an oxide layer formed via rapid thermal oxidation to a thickness of approximately thirty angstroms; however, thermal oxide layer 30 may also be formed using other suitable oxidation techniques to form an oxide layer of approximately twenty to forty angstroms in thickness using, for example, a conventional furnace. In alternative embodiments, thermal oxide layer 30 may include any suitable oxide formed by any suitable method to any suitable thickness so long as thermal oxide layer 30 is thick enough to provide a buffer between substrate 20 and the fast-diffused oxidants generated during the subsequent formation of a tunnel oxide layer 50 described in reference to FIG. 1C. Such a buffer prevents the fast-diffused oxidants from non-uniformly oxidizing the surface of substrate 20, thereby preventing the degradation of transistor performance along such surface of substrate 20.

FIG. 1B illustrates one embodiment of the formation of a silicon layer 40 disposed outwardly from thermal oxide layer 30. Silicon layer 40 is a polysilicon layer formed by first forming a thin layer of amorphous silicon and then annealing the amorphous silicon to form polysilicon material. The amorphous silicon is formed by depositing a thin layer of amorphous silicon of thirty to seventy angstroms in thickness, for example, using a low pressure chemical vapor deposition process or a rapid thermal chemical vapor deposition process. The anneal of such amorphous silicon layer may be accomplished using conventional furnace processes or a rapid thermal anneal process in order to form suitable polysilicon material with desired grain sizes. Alternatively, silicon layer 40 may be a polysilicon layer directly deposited to a thickness of thirty to seventy angstroms using a low pressure chemical vapor deposition process or a rapid thermal chemical vapor deposition process. The deposition of a polysilicon layer generally occurs at a higher temperature than the deposition of an amorphous silicon layer such as, for example, six hundred and twenty-five degrees Celsius as compared to five hundred fifty degrees Celsius for the amorphous silicon. Such direct deposition of polysilicon as silicon layer 40 removes the need for a separate anneal process.

FIG. 1C illustrates one embodiment of the formation of tunnel oxide layer 50 using thermal oxide layer 30 and silicon layer 40. Tunnel oxide layer 50 is a layer of silicon dioxide having a textured exterior surface and is formed by completely oxidizing silicon layer 40 via thermal oxidation. The complete thermal oxidation of silicon layer 40 may be accomplished using, for example, a conventional furnace or a rapid thermal oxidation process. Thereafter, tunnel oxide layer 50 includes the combination of thermal oxide layer 30 with the oxidized silicon layer 40. As earlier described, oxidants diffusing during the thermal oxidation of silicon layer 40 may penetrate thermal oxide layer 30 but will be buffered by the presence of thermal oxide layer 30 from impacting the surface of substrate 20. Thus, although the thermal oxidation of silicon layer 40 will result in a textured or roughened exterior surface of tunnel oxide layer 50, the interface between tunnel oxide layer 50 and substrate 20 will be relatively smooth in comparison, thereby preventing degradation in the performance of semiconductor device 10 by reducing carrier mobility. The formation of tunnel oxide layer 50 to a thickness of one hundred angstroms, for example, may have an exterior roughness ranging from five to ten angstroms in root-mean-square roughness. If a greater thickness of tunnel oxide layer 50 is desired, such as, for example, two hundred angstroms of silicon dioxide, a route-mean-square roughness of approximately ten to twenty angstroms may result.

FIG. 1D illustrates one embodiment of the formation of a gate layer 60 disposed outwardly from tunnel oxide layer 50. Gate layer 60 is polysilicon layer formed using a low pressure chemical vapor deposition process; however, other suitable processes for forming gate layer 60 may be utilized. Gate layer 60 may be formed, for example, to a thickness of three hundred angstroms. The roughened or textured exterior of tunnel oxide layer 50 prior to the formation of gate layer 60 results in a roughened interior surface of gate layer 60, such that a textured interface between tunnel oxide layer 50 and gate layer 60 is provided as shown in FIG. 1D. This roughened interface causes a smaller radius of curvature at several points along the interface between tunnel oxide layer 50 and gate layer 60, resulting in a lower tunneling barrier height because of the enhanced electrical field at the asperities of such points. Thus, an electrical field of lower strength can be utilized in order to achieve the Fowler-Nordheim tunneling necessary to, for example, erase flash memory cells that utilize floating gate structures. Such floating gate structures may be formed via a subsequent etch of gate layer 60 and separated from substrate 20 by tunnel oxide layer 50.

In alternative embodiments of this invention, the thickness of thermal oxide layer 30 may vary in response to the desired thickness of tunnel oxide layer 50, the tolerance of roughness at the interface between substrate 20 and tunnel oxide layer 50, and the desired roughness at the interface of floating gate layer 60 and tunnel oxide layer 50.

Although the present invention has been described using several embodiments, various changes and modifications may be suggested to one skilled in the art after a review of this description. It is intended that the present invention encompass such changes and modifications as fall within the scope of the appended claims.

What is claimed is:

1. A semiconductor device comprising:
a substrate;
an oxide layer disposed outwardly from the substrate; and
a polysilicon layer disposed outwardly from the oxide layer, the oxide layer having an interface between the oxide layer and the polysilicon layer, the interface having asperities such that the barrier potential between the polysilicon layer and the substrate is reduced in response to the asperities.

2. The semiconductor device of claim 1, wherein the oxide layer is a tunnel oxide layer formed without decreasing carrier mobility along a second interface between the oxide layer and the substrate.

3. The semiconductor device of claim 1, wherein the oxide layer is a tunnel oxide layer formed outwardly from the substrate without non-uniform oxidation of the surface of the substrate.

4. The semiconductor device of claim 1, wherein the oxide layer is a tunnel oxide layer formed using a thermal oxide layer and an oxidized polysilicon layer.

5. The semiconductor device of claim 1, wherein the oxide layer is a tunnel oxide layer formed by the oxidation of a polysilicon layer disposed outwardly from a thermal oxide layer, the thermal oxide layer that is disposed outwardly from the substrate, the thermal oxide layer shielding the substrate from the diffusion of oxidants during the oxidation of the polysilicon layer.

6. The semiconductor device of claim 1, wherein the oxide layer is a tunnel oxide and the polysilicon layer is a floating gate.

7. The semiconductor device of claim 1, wherein the oxide layer is a tunnel oxide layer formed using a thermal oxide layer and an oxidized polysilicon layer, the thermal oxide layer being formed to a thickness determined in response to a depth necessary to shield the substrate from the diffusion of oxidants during the oxidation of the polysilicon layer.

8. A method of semiconductor processing, the method comprising:
forming a thermal oxide layer outwardly from the surface of a substrate;
forming a polysilicon layer outwardly from the thermal oxide layer;
oxidizing the polysilicon layer; and
forming a gate layer outwardly from the oxidized polysilicon layer, the thermal oxide layer and the oxidized polysilicon layer forming a tunnel oxide layer separating the gate layer from the substrate.

9. The method of claim 8, wherein forming the thermal oxide layer comprises forming the thermal oxide layer to a thickness determined in response to the predicted diffusion of oxidants that occurs in response to the oxidation of the polysilicon layer.

10. The method of claim 8, and further comprising etching the gate layer to form a floating gate, the floating gate, the tunnel oxide layer, and the substrate forming a flash memory cell.

11. The method of claim 8, wherein oxidizing the polysilicon layer comprises forming asperities along an exterior surface of the oxidized polysilicon layer, the gate layer being formed outwardly from the exterior surface.

12. The method of claim 8, wherein oxidizing the polysilicon layer comprises oxidizing the polysilicon layer without non-uniform oxidation of the substrate.

13. The method of claim 8, wherein forming the polysilicon layer comprises forming the polysilicon layer to a thickness determined in response to the thickness of the thermal oxide layer.

14. The method of claim 8, wherein oxidizing the polysilicon layer comprises forming asperities along an exterior surface of the oxidized polysilicon layer without non-uniform oxidation of the substrate.

15. The method of claim 8, and further comprising shielding the substrate from a diffusion of oxidants initiated during the oxidation of the polysilicon layer, the thermal oxide layer proving such shielding.

16. A method of forming a semiconductor structure, the method comprising:
forming a thermal oxide layer outwardly from the surface of a substrate;
forming a polysilicon layer outwardly from the thermal oxide layer; and
oxidizing the polysilicon layer.

17. The method of claim 16, wherein forming the thermal oxide layer comprises forming the thermal oxide layer using rapid thermal oxidation.

18. The method of claim 16, wherein forming the polysilicon layer comprises:
forming an amorphous silicon layer; and
annealing the amorphous silicon layer.

19. The method of claim 16, wherein oxidizing the polysilicon layer comprises oxidizing the polysilicon layer using rapid thermal oxidation.

20. The method of claim 16, wherein forming the polysilicon layer comprises forming the polysilicon layer using a low pressure chemical vapor deposition process.

21. The method of claim 16, and further comprising:
forming a second polysilicon layer outwardly from the oxidized polysilicon silicon layer; and
etching the second polysilicon layer to form a gate layer.
